(19) United States
(12) Patent Application Publication
(10) Pub. No.: US 2005/0092231 A1
(43) Pub. Date: May 5, 2005

(54) Method and apparatus for making crystals without a pre-melt step

(76) Inventors: Daniel W. Hawtof, Corning, NY (US); Nicholas LeBlond, Painted Post, NY (US); Christopher S. Thomas, Horseheads, NY (US)

Correspondence Address: CORNING INCORPORATED, SP-TI-3-1, CORNING, NY, 14831, US

(21) Appl. No.: 10/696,125

(22) Filed: Oct. 29, 2003

(51) Int. Cl. C30B 9/00; C30B 11/00; C30B 17/00; C30B 21/02; C30B 28/06

(52) U.S. Cl. 117/81; 117/83

(57) ABSTRACT

A method of making crystals includes suspending a porous preform made of a crystal raw material in a hermetically-sealed chamber, heating the porous preform to a selected treatment temperature that enables reaction between a fluorinating agent and oxide impurities in the porous preform and reacting the fluorinating agent with the oxide impurities at the selected treatment temperature for a selected time period, filling a crucible in the hermetically-sealed chamber with a melt formed from at least a portion of the porous preform, and progressively moving the melt through a temperature gradient zone defined inside the hermetically-sealed chamber. An apparatus for making crystals includes a hermetically-sealed muffle furnace made of a non-porous refractory material, at least one port for entry and exit of gaseous substance within the muffle furnace, at least two temperature-controlled zones defined inside the muffle furnace, a crystal growth crucible disposed inside the muffle furnace, an actuator operable to translate the crucible along a length of the muffle furnace, and means for suspending a preform inside the muffle furnace.

### BACKGROUND OF INVENTION

The invention relates to methods and apparatus for making crystals. While not wishing to be bound to a particular group of crystals, it is convenient in the following discussion to focus on a particular group of crystals. One group of crystals of interest is optical fluoride crystals. Single-grained optical fluoride crystals are useful in applications requiring transmission at short wavelengths, e.g., in the vacuum ultraviolet region. At present, CaF₂ crystal is the most viable lens material for 157-nm microlithography.

Optical fluoride crystals as well as other types of crystals can be grown in two steps. The first step is a pre-melt step in which crystal raw material in powder or granular form is melted and then rapidly cooled into a solid body, which herein will be referred to as a crystal pre-melt. The second step is a growth step in which the crystal pre-melt is melted and then used to grow one or more crystals.

Single-grained crystals are commonly grown using the Bridgman-Stockbarger process. As illustrated in FIG. 1A, the Bridgman-Stockbarger process takes place in a vertical furnace 100 having an upper zone 102 and a lower zone 104. A middle or thermal gradient zone 106 is defined between the upper zone 102 and the lower zone 104 by making the temperature of the upper zone 102 higher than the temperature of the lower zone 104. The growth step starts with loading of a crystal pre-melt 108 into a crystal growth crucible 110. With the growth crucible 110 in the upper zone 102, the upper zone 102 is then heated to a temperature sufficient to melt the crystal pre-melt 108. After melting the crystal pre-melt 108, the growth crucible 110 is lowered from the upper zone 102, through the thermal gradient zone 106, into the lower zone 104. As shown in FIG. 1B, as the growth crucible 110 passes through the thermal gradient zone 106, a phase transition occurs inside the molten crystal pre-melt 108a, creating a crystal front 112. The crystal front 112 propagates inside the growth crucible 110, within the molten crystal pre-melt 108a, as long as the growth crucible 110 continues to move downwardly into the lower zone 104.

Returning to FIG. 1A, the crystal pre-melt 108 is made by subjecting relatively pure crystal raw material in powder or granular form to a pre-melt step. The main purpose of the pre-melt step is to increase the bulk density of the crystal raw material so that the volume of the crystal growth furnace can be used efficiently. For example, synthetic CaF₂ powder has an apparent density of 1.1 g/cm³, and crystals grown from CaF₂ powder have an apparent density that is close to the theoretical density of CaF₂, i.e., 3.18 g/cm³. Thus, if synthetic CaF₂ powder is used directly as the crystal raw material, two-thirds of the volume of the crystal growth furnace will not be used, or at least, not used efficiently. Through a pre-melt step, the apparent density of the CaF₂ raw material can be increased to approximately 2.2 g/cm³, which would be much closer to the density of the grown CaF₂ crystal.

The pre-melt step typically includes a treatment step in which oxide impurities are scavenged from the crystal raw material prior to melting the crystal raw material. Commonly, the treatment step involves mixing a solid fluorinating agent, e.g., PbF₂, ZnF₂, or polytetrafluoroethylene (PTFE), with the crystal raw material and then heating the mixture to the melting point of the crystal raw material. At this temperature, the solid fluorinating agent reacts with oxides in the crystal raw material to form volatile gases that escape from the crystal raw material. However, use of solid fluorinating agent to scavenge oxide impurities has a drawback in that impurities such as Pb²⁺, Zn²⁺, or C can remain in the crystal raw material after treatment. For optical fluoride crystals, the presence of these impurities, even at trace levels, can result in absorption bands that are detrimental to transmission at wavelengths below 200 nm.

Recently, gaseous fluorinating agents, such as CF₄, HF, SF₆, and BF₃, have been proposed as alternatives to solid fluorinating agents in scavenging oxide impurities. With gaseous fluorinating agents, the risk of leaving harmful impurities such as Pb²⁺, Zn²⁺, or C in the grown crystal is relatively low or non-existent. However, use of gaseous fluorinating agents in scavenging oxide impurities in conventional settings poses various challenges. For example, the furnace and furnace elements, e.g., crucibles, thermocouples, and resistors, used in the pre-melt step are typically made of pure graphite or other materials that are susceptible to corrosion by the gaseous fluorinating agents, especially in the presence of oxygen atmosphere and/or at elevated temperatures. For example, CF₄ attacks thermocouples at temperatures above 1100° C. Further, pure graphite is porous and tends to outgas. Outgassing of H₂O, CO₂, or CO from the graphite parts may contribute to contamination of the crystal pre-melt after treatment.

The pre-melt step typically takes between 12 and 15 days, occupying a furnace that could otherwise be used for actual growth of the crystals and thus hampering productivity. To facilitate melting of the crystal pre-melt during the crystal growth step, the crystal pre-melt typically has to be crushed before it is loaded into the crystal growth crucible. This crushing action is often a source of metallic and other forms of contamination in the grown crystal. Further, the growth furnace is open to air while the crystal pre-melt is being loaded into the growth furnace. This exposure can be an additional source of contamination.

From the foregoing, there is desired a method of making crystals that minimizes or eliminates one or more of the aforementioned concerns.

### SUMMARY OF INVENTION

In one aspect, the invention relates to a method of making crystals which comprises suspending a porous preform made of a crystal raw material in a hermetically-sealed chamber, heating the porous preform to a selected treatment temperature that enables reaction between a fluorinating agent and oxide impurities in the porous preform, reacting the fluorinating agent with the oxide impurities at the selected temperature for a selected time period, forming a melt from at least a portion of the porous preform, filling a crucible in the hermetically-sealed chamber with the melt, and progressively moving the melt through a temperature gradient zone defined inside the hermetically-sealed chamber to grow one or more crystals.

In another aspect, the invention relates to an apparatus for making crystals which includes a hermetically-sealed muffle furnace made of a non-porous refractory material, at least one port for entry and exit of gaseous substance within the muffle furnace, at least two temperature-controlled zones defined inside the muffle furnace, a crystal growth crucible disposed inside the muffle furnace, an actuator operable to translate the crucible along a length of the muffle furnace, and means for suspending a porous preform above the crucible.

Other features and advantages of the invention will be apparent from the following description and the appended claims.

### BRIEF DESCRIPTION OF DRAWINGS

FIGS. 1A and 1B illustrate a prior-art method of growing a crystal.

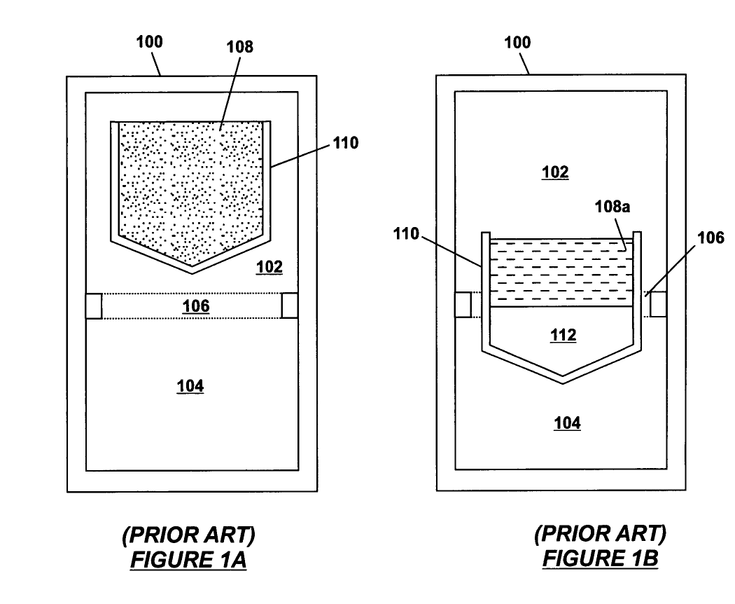

FIG. 2A is a schematic of an apparatus for making crystals according to one embodiment of the invention.

FIG. 2B shows an apparatus for making oriented crystals according to another embodiment of the invention.

FIG. 2C shows a porous preform being melted into a waiting crucible in a muffle furnace in accordance with one embodiment of the invention.

FIG. 2D shows molten material moved through a temperature gradient zone in a muffle furnace to grow one or more crystals.

### DETAILED DESCRIPTION OF PREFERRED EMBODIMENTS

The invention will now be described in detail with reference to a few preferred embodiments, as illustrated in accompanying drawings. In the following description, numerous specific details are set forth in order to provide a thorough understanding of the invention. However, it will be apparent to one skilled in the art that the invention may be practiced without some or all of these specific details. In other instances, well-known features and/or process steps have not been described in detail in order to not unnecessarily obscure the invention. The features and advantages of the invention may be better understood with reference to the drawings and discussions that follow.

Embodiments of the invention provide an apparatus and a method for making crystals from crystal raw material without a pre-melt step. The apparatus includes a muffle furnace made of a non-porous refractory material. Treatment of crystal raw material to remove oxide impurities and growing of crystals from the treated material all occur in the muffle furnace; therefore, the treated material is not open to air prior to being used in growing the crystals. By constructing the muffle furnace from a non-porous refractory material, the crystal raw material is protected from contamination after treatment through outgassing of the muffle furnace material.

The type of crystals made by the method and apparatus of the invention would depend on the composition of the crystal raw material from which the crystals are made. One group of crystal raw material that is of interest herein is fluoride crystal raw material. In one embodiment, the fluoride crystal raw material includes a metal fluoride selected from the group consisting of CaF₂, BaF₂, MgF₂, SrF₂, LiF, NaF, (M₁)ₓ(M₂)₁₋ₓF₂, and M₃AlF₆, and mixtures thereof, where M₁ is selected from the group consisting of Li and K; M₂ is selected from the group consisting of Ca, Ba, Mg, and Sr; M₃ is selected from the group consisting of Li, Na, K, Rb, and Cs; and x is in the range from 0 to 1, preferably in a range from 0.01 to 0.99. The fluoride crystal raw material may also include mixed metal fluorides wherein a metal fluoride selected from the lanthanide series, for example, lanthanum, ytterbium, yttrium, or others of the series, is used as one of M₁ or M₂, or is used in addition to M₁ and M₂. Those skilled in the art will recognize the possible combinations. Optionally, a small amount of a solid fluorinating agent, e.g., 0.5 to 2 wt % of PbF₂, ZnF₂, or other solid fluorinating agent, may be mixed with the fluoride crystal raw material.

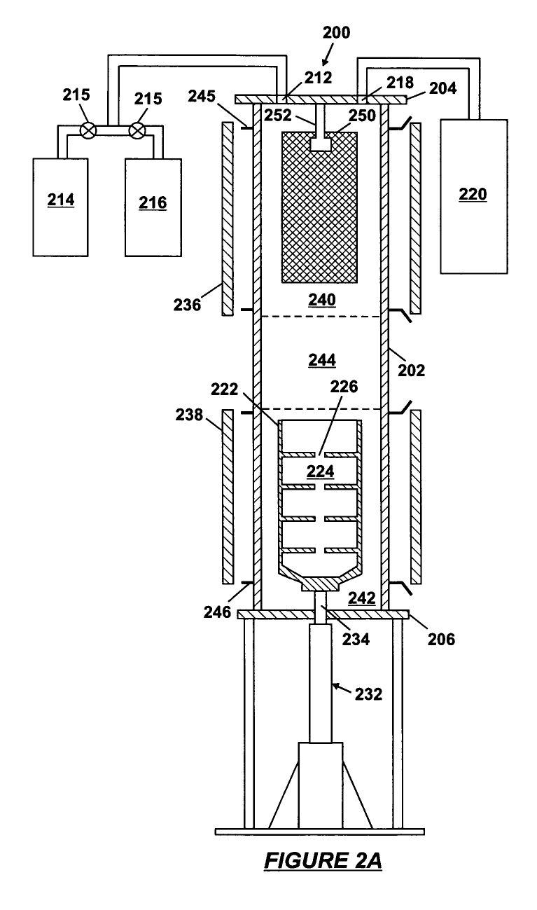

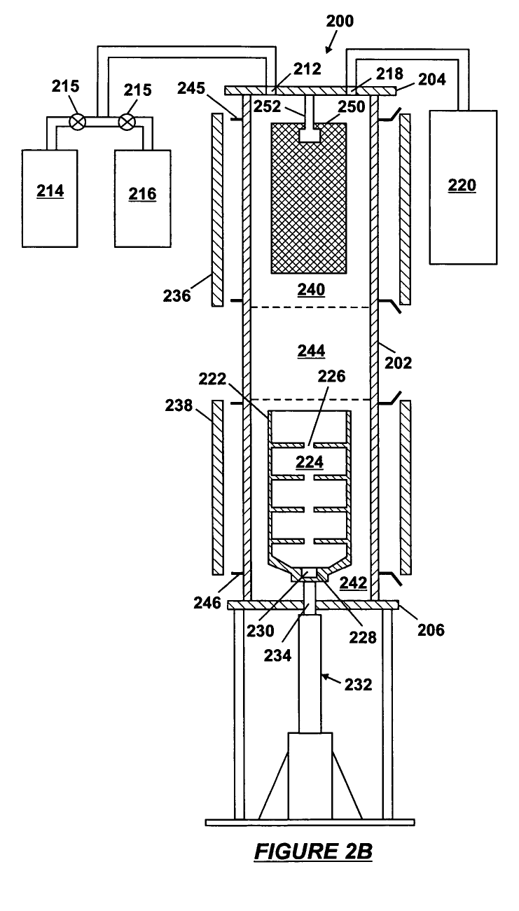

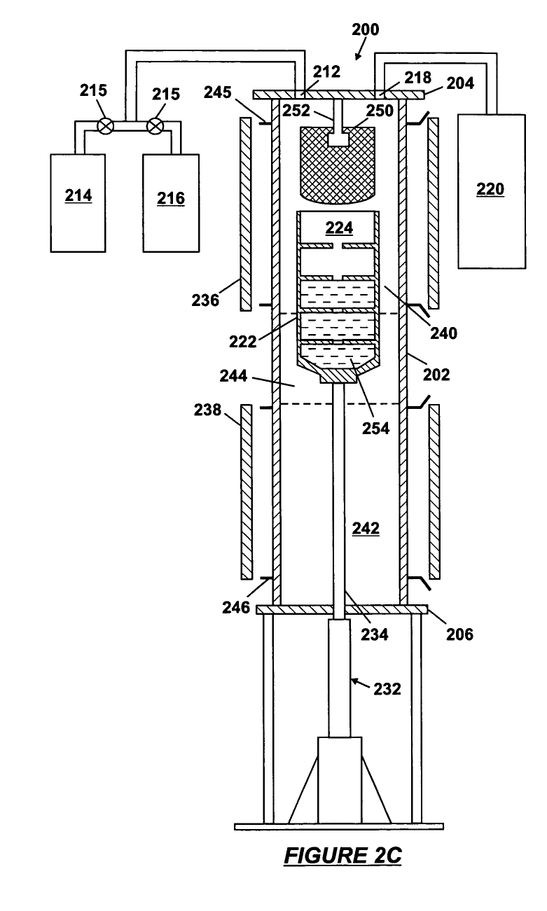

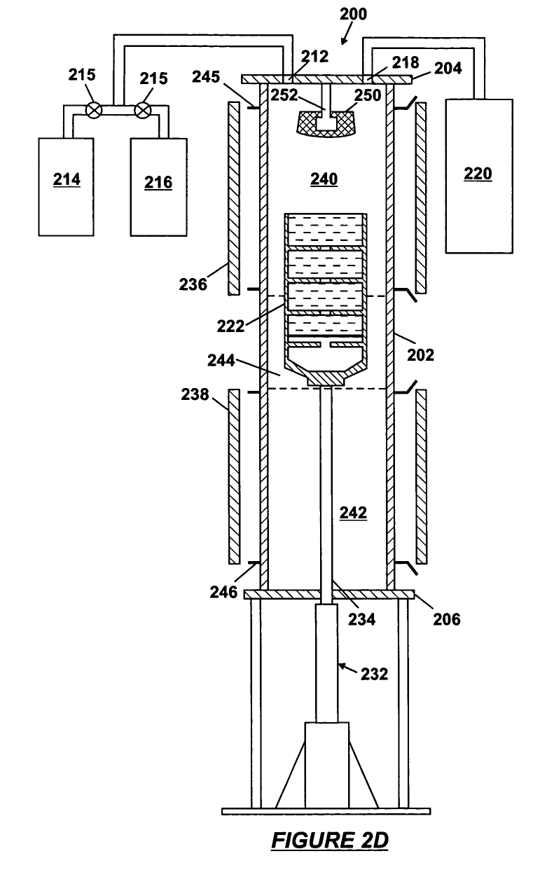

FIG. 2A shows an apparatus 200 for making one or more crystals without a pre-melt step in accordance with one embodiment of the invention. The apparatus 200 includes a muffle furnace 202 that is constructed from a non-porous refractory material. Examples of suitable non-porous refractory materials include quartz, alumina, silicon carbide, vitreous carbon, vitreous graphite, glassy carbon-coated graphite, and a combination of these materials. These materials are also inert in that they are not expected to react with the process gases under the process conditions in which crystal raw material will be treated and formed into crystals inside the muffle furnace 202. By constructing the muffle furnace 202 from a non-porous refractory material, the crystals made inside the muffle furnace 202 are protected from contamination through outgassing of the muffle furnace material.

The upper and lower ends of the muffle furnace 202 are covered with end caps 204, 206, respectively. Preferably, the end caps 204, 206 make a sealed contact with the muffle furnace 202, providing a hermetically-sealed environment inside the muffle furnace 202. A variety of sealing mechanisms, such as metal-to-metal seal, O-ring seal, etc., can be used between the muffle furnace 202 and the end caps 204, 206 to achieve the sealed contact. To avoid contamination of the crystal raw material after treatment through outgassing of the end cap material, the end caps 204, 206 are also preferably constructed from a non-porous refractory material, such as listed above for the muffle furnace 202.

Either or both of the end caps 204, 206 or the wall of the muffle furnace 202 may include one or more ports through which gases can flow into and out of the muffle furnace 202. For example, as illustrated in FIGS. 2A-2D, an inlet port 212 is provided in the end cap 204. The inlet port 212 may be selectively connected to gas sources 214, 216. As an example, the gas source 214 could contain a gaseous fluorinating agent, and the gas source 216 could contain an inert gas. Valves 215 may be provided to control rate of flow from the gas sources 214, 216 into the muffle furnace 202. As also illustrated in FIGS. 2A-2D, an outlet port 218 is also provided in the end cap 204. The outlet port 218 may be connected to an effluent treatment chamber 220, which may include a scrubber (not shown) to remove or decompose any gaseous fluorinating agent in the effluent of the muffle furnace 202. Examples of scrubbers include heated metal oxide such as soda lime or a plasma system. Although not shown, a vacuum system could also be incorporated to suck out gas from the muffle furnace 202 through the outlet port 218.

In one embodiment, a crucible stack 222 is supported inside the muffle furnace 202. The crucible stack 222 may include any number of crucibles or crystal growth chambers 224 stacked vertically. Typically, the number of crucibles or crystal growth chambers in the crucible stack 222 can range from 1 to 20. The crucible stack 222 may be made of a refractory material that may be porous or non-porous. Preferably, the crucible stack 222 is made of a non-porous refractory material, such as previously listed for the muffle furnace 202. As shown in FIG. 2A, the crucibles 224 in the stack 222 communicate through holes 226 in their bottom walls. As shown in FIG. 2B, the crucible 224 at the bottom of the stack 222 may include a seed crystal holder 228 at its base. The seed crystal holder 228 is for receiving a seed crystal 230 having a specific crystallographic orientation and is needed only if an oriented crystal is to be grown. In practice, the seed crystal 230 would be selected to have a similar phase and melting point as the crystal to be grown.

Returning to FIG. 2A, a lift mechanism 232 is coupled to the crucible stack 222. As an example, the lift mechanism 232 could be a fluid-powered actuator, such as a hydraulic or pneumatic actuator, or a mechanical actuator. When operated, the lift mechanism 232 translates the crucible stack 222 along an axial length of the muffle furnace 202. The lift mechanism 232 may also have a capability to rotate the crucible stack 222 inside the muffle furnace 202. In one embodiment, the lift mechanism 232 includes a sliding member 234, such as a piston or rod, which extends from the outside into the muffle furnace 202 through the end cap 206. Preferably, one or more seals (not shown) are fitted between the sliding member 234 and the end cap 206 to maintain the gas-tight environment inside the muffle furnace 202, particularly while the crystal material is being processed inside the muffle furnace 202.

Different temperature zones can be defined inside the muffle furnace 202 through the use of one or more heaters. For example, a variable temperature heater 236 is positioned adjacent or around an upper section of the muffle furnace 202 to define an upper (treatment/melting) zone 240 inside the muffle furnace 202. Also, a variable temperature heater 238 is positioned adjacent or around a lower section of the muffle furnace 202 to define a lower (cooling/annealing) zone 242 inside the muffle furnace 202. The heaters 236, 238 can be independently controlled to maintain different temperatures in the upper and lower zones 240, 242, respectively. A middle temperature-gradient zone 244 is defined between the upper zone 240 and the lower zone 242 when the temperatures in the upper and lower zones 240, 242 are different. Typically, a heater is not positioned around or adjacent the middle zone 244, and the desired temperature gradient in the middle zone 244 is achieved primarily by adjusting the temperatures in the zones 240, 242.

More than two heaters can be positioned adjacent or around different sections of the muffle furnace 202 to allow further refinement of the temperature zones in the muffle furnace. Alternatively, one or more heaters may be translated along the length of the muffle furnace 202 to achieve the desired temperature zones in the muffle furnace. In addition, each of the heaters 236, 238 can have one or more heating elements, each of which can be independently controlled in order to form a temperature gradient within the upper or lower zone 240, 242 if so desired. This feature is particularly useful with regard to the lower zone heater 238 when annealing is to be carried out within the lower zone 238 as the crucible stack 222 is lowered. The heaters 236, 238 are preferably mounted outside of the muffle furnace 202 to prevent them from contaminating the crystal raw material processed inside the muffle furnace and to prevent them from being damaged by the process gases.

Although not shown, insulation material may be disposed between the heaters 236, 238 to allow greater control over the temperature profile in the temperature gradient zone 244. Insulation material could also be provided around the outside of the heaters 236, 238 to contain heat around the muffle furnace 202. The temperature in the upper and lower zones 240, 242 can be measured using thermocouples 245, 246, respectively, and the output of the thermocouples 245, 246, respectively, can be used to control the power delivered to the heaters 236, 238 so that desired temperatures are maintained in the upper and lower zones 240, 242. To avoid contact between the thermocouples 245, 246 and process gases in the muffle furnace 202, the thermocouples may be mounted on the outside wall of the muffle furnace 202 instead of inside the muffle furnace. In an alternate embodiment, the sealed muffle furnace 202 could be inserted into a conventional furnace, wherein the conventional furnace includes the furnace elements, e.g., heaters, necessary to provide the desired temperature zones in the muffle furnace.

The invention is not limited to the use of an external heat source, such as heaters 236, 238, to provide a desired temperature profile in the upper and lower zones 240, 242. Inductive heating or resistive heating could also be used to provide the desired temperatures in the upper and lower zones 240, 242. For example, in a situation where the muffle furnace is made of a conductive non-porous refractory material, such as vitreous graphite, vitreous carbon, or silicon carbide, the muffle furnace 202 could be used as an electromagnetic induction susceptor when coupled with an induction coil. Alternatively, the muffle furnace 202 itself could serve as a heating element if a controlled current is placed across it.

Referring to FIG. 2A, a method of making one or more crystals includes suspending a porous preform 250 made of crystal raw material, such as fluoride crystal raw material, in the upper zone 240 of the muffle furnace 202, above the crucible stack 222. In one embodiment, the porous preform 250 is suspended by a handle 252 having one end attached to the porous preform 250 and the other end coupled to the end cap 204. The handle 252 could be made of a crystal or a non-porous refractory material, such as listed above for the muffle furnace material. Alternatively, the porous preform 250 could be held by, for example, a claw-like device (not shown) grasping the outside of the preform 250. The claw-like device is such that it exerts continuous pressure on the porous preform 250 so that the preform is held in position above the crucible stack 222 during the treatment and melting steps.

In one embodiment, the porous preform 250 is made by isostatic pressing of crystal raw material, as taught by Malcolm Ivy in U.S. patent application Ser. No. 10/611,506 (assigned to Corning Incorporated). Briefly, the process for forming the porous preform 250 includes loading relatively pure crystal raw material in powder form into a flexible mold and then applying isostatic pressure to the mold to compress the crystal raw material. The isostatic pressing could be cold, warm, or hot. The handle 252 could be inserted in the top of the crystal raw material so that it is molded to the top of the crystal raw material during the isostatic pressing. Alternatively, a notch can be cut at the top of the porous preform 250 after isostatic pressing, and the handle 252 can be inserted in the notch to facilitate handling of the porous preform 250.

Treatment of the porous preform 250 to remove oxide impurities can begin once the porous preform 250 is suspended in the upper zone 240 of the muffle furnace 202 and the muffle furnace 202 is hermetically sealed. Treatment may be with a solid fluorinating agent already in the porous preform 250 and/or with a gaseous fluorinating agent that will be introduced into the muffle furnace 202. Before reacting the solid and/or gaseous fluorinating agent with the porous preform 250, the muffle furnace 202 is purged and filled with an inert gas, such as argon, helium, or nitrogen. Alternatively, any gas in the muffle furnace 202 may be evacuated before filling the furnace 202 with the inert gas. As the muffle furnace 202 is filled with the inert gas, the muffle furnace 202, which is initially at room temperature, is heated to a treatment temperature. The treatment temperature should be high enough to enable reaction between the solid or gaseous fluorinating agent and the porous preform 250. To facilitate diffusion of gases through the porous preform 250, the treatment temperature should not be so high as to significantly increase the density of the preform. Heating to treatment temperature can occur in one step or in multiple steps.

In one embodiment, when the treatment temperature is reached, a solid fluorinating agent already embedded in the porous preform 250 reacts with oxide impurities in the porous preform 250 to produce volatile gases, which are carried away to the treatment chamber 220 through the outlet port 218.

In another embodiment, when the treatment temperature is reached, the inert gas in the muffle furnace 202 is replaced with a gaseous fluorinating agent, such as CF₄, NF₃, SF₆, BF₃, C₂F₄, HF, F₂, or a mixture of these fluorides. The gaseous fluorinating agent may be carried into the muffle furnace 202 in a stream of inert gas, such as argon, helium, or nitrogen. The amount of gaseous fluoride in the inert gas stream may be in a range from 1% to 100% by weight. The inert gas may be premixed with the gaseous fluorinating agent or provided from a separate source. In one embodiment, the flow rate of the gaseous fluorinating agent is adjusted such that the pressure in the muffle furnace 202 is in a range from 0.1 to 5 atm, preferably around 1 atm. The gaseous fluorinating agent is selected based on its decomposition temperature and the melting point of the crystal material. For example, CF₄ has a high bond energy (536 KJ/mol) and is expected to be an effective oxide scavenger at temperatures of 1000° C. and above and is better suited for treatment of high-melting materials such as CaF₂. NF₃ and SF₆ are expected to produce similar scavenging effect as CF₄ at temperatures closer to 200 to 400° C. and 500 to 800° C., respectively, and are thus better suited for the treatment of low-melting materials. In one embodiment, the treatment temperature is selected to be in the range of approximately 50 to 500° C. below the melting point of the material being purified.

The porous preform 250 is exposed to the gaseous fluorinating agent for a time period, for example, 1 to 240 hours, preferably 1 to 100 hours. During this period, the gaseous fluorinating agent reacts with oxide impurities in the porous preform 250 to produce volatile gases, which are carried away to the treatment chamber 220 through the outlet port 218. Because there is no crucible in the flow path of the gaseous fluorinating agent and the porous preform 250, the gaseous fluorinating agent can diffuse through the porous preform 250 without delay, reducing process time. Further, contamination of the porous preform 250 from crucible material is avoided. Further, the crucible stack 222 below the porous preform 250 is purified by the gaseous fluorinating agent while the porous preform 250 is being purified. The purified crucible stack 222 will later be used to grow the crystal(s).

The amount of oxide impurities removed from the porous preform 250 depends on the exposure time and treatment temperature. In general, the time required to remove oxide impurities decreases as treatment temperature increases. Also, the closer the treatment temperature is to the melting point of the crystal material, the shorter the time required to reduce the oxide impurity level of the crystal material. Gas analysis of the effluent from the muffle furnace 202 is used to determine the completion of the treatment step. For example, the oxygen concentration of the muffle furnace effluent may be measured, and when this oxygen concentration falls below a predetermined threshold, the treatment process can be stopped.

When the treatment process is completed, the muffle furnace 202 is purged with an inert gas, such as argon, helium, or nitrogen, or degassed to vacuum pressure (e.g., 10⁻⁵ torr or less). Then, the porous preform 250 is partially or entirely melted into the waiting crucible stack 222. The ability to partially melt the porous preform 250 opens possibilities for growing crystals in batches inside the muffle furnace 202. The porous preform 250 could be melted in-situ in the upper zone 240 by increasing the temperature in the upper zone 240 above the melting point of the crystal material. Alternatively, a separate melting zone may be provided inside the muffle furnace 202 in which the porous preform 250 can be melted into the waiting crucible stack 222. In FIG. 2C, the crucible stack 222 is moved into the upper zone 240 to receive the molten material 254 formed by melting of the porous preform 250. The crucibles 224 are filled from the bottom to the top as opposed to the top-down melting used in current crystal growth processes, which means that fewer voids will be trapped in the molten material 254.

In FIG. 2D, the crucible stack 222 with the molten material 254 is slowly translated from the upper zone 240 through the temperature gradient zone 244 into the lower zone 242. As an example, the translation speed of the crucible stack 222 could be in a range from 0.5 mm/hr to 5 mm/hr. The temperature gradient zone 244 is formed by making the temperature in the lower zone 242 lower than the temperature in the upper zone 240. As the crucible stack 222 passes through the temperature gradient zone 244, a solid-liquid growth front 256 is created by a phase transition inside the molten material 254. The solid-liquid growth front 256 propagates inside the crucible stack 222, within the molten material 254, as long as the crucible stack 222 continues to move downwardly into the lower zone 242. The solid-liquid growth front 256 can be initially formed on an oriented seed crystal (not illustrated in FIG. 2D, see FIG. 2B) so that it conforms to the crystallographic orientation of the seed crystal as it propagates inside the crucible stack 222. As is well known in the art, the grown crystal can be cooled or annealed in the lower zone 242 using a variety of cooling schedules. If the birefringence of the cooled or annealed crystal is not low enough, the crystal may be further annealed in a separate annealing furnace.

The invention provides many advantages. The invention bypasses the pre-melt step of the current crystal growth processes and integrates treatment of crystal raw material with the crystal growth step. This method of making crystals reduces contamination of the crystal raw material used in growing the crystal and frees up furnaces used for pre-melting in the current crystal growth processes. The present invention eliminates the need for a pre-melt crucible to hold crystal raw material. Instead, the crystal raw material is provided in the form of a porous preform that can be suspended and processed while being suspended. Without the pre-melt crucible in the way, quicker diffusion of gaseous fluorinating agent through the porous preform is enabled and contamination of the porous preform with crucible material is avoided.

High throughput is enabled by using a crucible stack with multiple crucibles or crystal growth chambers. Crystals can be grown in batches through a series of partial melting of porous preform and growing of one or more crystals from the melt. The porous preform is purified in a muffle furnace in that is made of a non-porous inert material. Thus, the porous preform is not susceptible to contamination through outgassing of the muffle furnace material. Furnace elements such as thermocouples and heaters can be mounted on the outside of the muffle furnace to prevent them from contaminating the porous preform and/or from being attacked by the process gases.

The level of process control over temperature, pressure, and process gas is better in the hermetically-sealed muffle furnace environment than in a porous graphite furnace. There is ability to both pressurize the muffle furnace for the treatment step and provide a vacuum for the growth step. There is potential to provide an inert gas environment for growth versus requiring a vacuum. This reduces waiting time for good vacuum, and the heat capacity and conductivity of the inert gas would provide more temperature uniformity around the crystal. There is ability to start the liquid filling of the growth crucible from the bottom up versus the top down melting provided today. This filling method traps less voids and enables better outgassing and zone refinement of contamination.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

1. A method of making crystals, comprising:
suspending a porous preform made of a crystal raw material in a hermetically-sealed chamber;
heating the porous preform to a selected treatment temperature that enables reaction between a fluorinating agent and oxide impurities in the porous preform;
reacting the fluorinating agent with the oxide impurities at the selected treatment temperature for a selected time period;
forming a melt from at least a portion of the porous preform;
filling a crucible in the hermetically-sealed chamber with the melt; and
progressively moving the melt through a temperature gradient zone defined inside the hermetically-sealed chamber to grow one or more crystals.

2. The method of claim 1, wherein the hermetically-sealed chamber is provided by a hermetically-sealed muffle furnace made of a non-porous refractory material.

3. The method of claim 2, wherein the non-porous refractory material comprises one selected from the group consisting of quartz, alumina, silicon carbide, vitreous carbon, vitreous graphite, glass carbon-coated graphite, and combinations thereof.

4. The method of claim 1, wherein the fluorinating agent is in gaseous form and is selected from the group consisting of CF₄, NF₃, SF₆, BF₃, C₂H₄, HF, F₂, and mixtures thereof, and similar fluorinating gases known in the art.

5. The method of claim 4, wherein the fluorinating agent is supplied into the hermetically-sealed chamber in a stream of inert gas.

6. The method of claim 4, wherein the pressure in the hermetically-sealed chamber while reacting the fluorinating agent with the porous preform is in the range of 0.1 to 5 atm.

7. The method of claim 4, wherein the porous preform is heated to a treatment temperature in the presence of an inert gas prior to exposing the porous preform to the gaseous fluorinating agent.

8. The method of claim 1, wherein reacting the fluorinating agent with the oxide impurities comprises removing volatile gases formed during reaction of the fluorinating agent with the oxide impurities from the hermetically-sealed chamber, and wherein forming the melt occurs in an inert atmosphere.

9. The method of claim 1, wherein the fluorinating agent is in solid form and mixed into the crystal raw material in a range from 0.5 to 2 wt %.

10. The method of claim 1, wherein progressively moving the melt occurs in an inert atmosphere or vacuum.

11. The method of claim 1, wherein the crystal raw material comprises a metal fluoride selected from the group consisting of CaF₂, BaF₂, MgF₂, SrF₂, LiF, NaF, (M₁)ₓ(M₂)₁₋ₓF₂, and M₃AlF₆, and mixtures thereof; and where M₁ is selected from the group consisting of Li, K, and lanthanide series metal fluorides; M₂ is selected from the group consisting of Ca, Ba, Mg, Sr, and lanthanide series metal fluorides; M₃ is selected from the group consisting of Li, Na, K, Rb, and Cs; and x is in a range from 0 to 1.

12. The method of claim 11, wherein the crystal raw material further comprises a lanthanide series metal fluoride mixed with the metal fluoride.

13. The method of claim 1, wherein the selected time period is in the range of 1 to 240 hours, and the selected treatment temperature is dependent on the melting point of the crystal raw material and is in the range of 50 to 500° C. below the melting point of the crystal raw material.

14. An apparatus for making crystals, comprising:
a hermetically-sealed muffle furnace made of a non-porous refractory material;
at least one port for entry and exit of gaseous substance within the muffle furnace;
at least two temperature-controlled zones defined inside the muffle furnace;
a crystal growth crucible disposed inside the muffle furnace;
an actuator operable to translate the crucible along a length of the muffle furnace; and
means for suspending a porous preform above the crucible.

15. The apparatus of claim 14, wherein the non-porous refractory material comprises one selected from the group consisting of quartz, alumina, silicon carbide, vitreous carbon, vitreous graphite, glass carbon-coated graphite, and combinations thereof.

16. The apparatus of claim 14, wherein the crucible is made of a non-porous refractory material selected from the group consisting of quartz, alumina, silicon carbide, vitreous carbon, vitreous graphite, glass carbon-coated graphite, and combinations thereof.

17. The apparatus of claim 14, wherein the at least one port is provided in an end cap fitted in sealed contact at an end of the muffle furnace, and wherein the cap is made of a non-porous refractory material selected from the group consisting of quartz, alumina, silicon carbide, vitreous carbon, vitreous graphite, glass carbon-coated graphite, and combinations thereof.

18. The apparatus of claim 14, wherein the actuator is operable to rotate the crucible about the axial axis of the muffle furnace.

19. The apparatus of claim 14, wherein the crucible comprises one or more crystal growth chambers stacked vertically.

20. The apparatus of claim 14, wherein the temperature-controlled zones are defined by one or more heaters disposed external to the muffle furnace, one or more conductive portions of the muffle furnace, and combinations thereof.
